(19) United States
(12) Patent Application Publication
(10) Pub. No.: US 2016/0072054 A1
(43) Pub. Date: Mar. 10, 2016

(54) METHOD TO MAKE MRAM WITH SMALL CELL SIZE

(71) Applicant: Yimin Guo, San Jose, CA (US)

(72) Inventor: Yimin Guo, San Jose, CA (US)

(73) Assignee: T3MEMORY, INC., Saratoga, CA (US)

(21) Appl. No.: 14/479,353

(22) Filed: Sep. 7, 2014

(51) Int. Cl. H01L 43/12; H01L 43/08; H01L 43/10; H01L 43/02

(52) U.S. Cl. CPC H01L 43/12; H01L 43/02; H01L 43/08; H01L 43/10

(57) ABSTRACT

A method to make magnetic random access memory with extremely small cell size is provided. Using atomic layer deposition (ALD) technique, a very thin film of hard mask material is uniformly grown on the vertical spatial walls of a pre-form. Stand alone hard mask is formed after removing the pre-form. Array of magnetic memory cells are formed by reactive ion etch (RIE) or ion milling using such small hard mask. This way, the dimension of the hard mask is no longer limited by photolithography tool capability, instead, it is controlled by ALD-grown hard mask film thickness which can be made extremely thin.

### RELATED APPLICATIONS

This application claims the priority benefit of U.S. Provisional Application No. 61,875,089 filed on Sep. 8, 2013, which is incorporated herein by reference.

### BACKGROUND OF THE INVENTION

1. Field of the Invention

This invention relates generally to a methods of fabricating magnetic random access memory element having an ultra-small cell size using a spatial wall process.

2. Description of the Related Art

In recent years, magnetic random access memories (hereinafter referred to as MRAMs) using the magnetoresistive effect of ferromagnetic tunnel junctions (also called MTJs) have been drawing increasing attention as the next-generation solid-state nonvolatile memories that can also cope with high-speed reading and writing. A ferromagnetic tunnel junction has a three-layer stack structure formed by stacking a recording layer having a changeable magnetization direction, an insulating tunnel barrier layer, and a fixed layer that is located on the opposite side from the recording layer and maintains a predetermined magnetization direction. Corresponding to the parallel and anti-parallel magnetic states between the recording layer magnetization and the reference layer magnetization, the magnetic memory element has low and high electrical resistance states, respectively. Accordingly, a detection of the resistance allows a magnetoresistive element to provide information stored in the magnetic memory device.

Typically, MRAM devices are classified by different write methods. A traditional MRAM is a magnetic field-switched MRAM utilizing electric line currents to generate magnetic fields and switch the magnetization direction of the recording layer in a magnetoresistive element at their cross-point location during the programming write. A spin-transfer torque (or STT)-MRAM has a different write method utilizing electrons' spin momentum transfer. Specifically, the angular momentum of the spin-polarized electrons is transmitted to the electrons in the magnetic material serving as the magnetic recording layer. According to this method, the magnetization direction of a recording layer is reversed by applying a spin-polarized current to the magnetoresistive element. As the volume of the magnetic layer forming the recording layer is smaller, the injected spin-polarized current to write or switch can be also smaller.

Further, as in a so-called perpendicular spin-transfer torque magnetic random access memories (pSTT-MRAM), both of the two magnetization films have easy axis of magnetization in a direction perpendicular to the film plane due to their strong magnetic crystalline anisotropy (shape anisotropies are not used), and accordingly, the device shape can be made smaller than that of an in-plane magnetization type.

To record information or change resistance state, typically a recording current is provided by its CMOS transistor to flow in the stacked direction of the magnetoresistive element, which is hereinafter referred to as a “vertical spin-transfer method.” Generally, constant-voltage recording is performed when recording is performed in a memory device accompanied by a resistance change. In a pSTT-MRAM, the majority of the applied voltage is acting on a thin oxide layer (tunnel barrier layer) which is about 10 angstroms thick, and, if an excessive voltage is applied, the tunnel barrier breaks down. More, even when the tunnel barrier does not immediately break down, if recording operations are repeated, the element may still become nonfunctional such that the resistance value changes (decreases) and information readout errors increase, making the element un-recordable. Furthermore, recording is not performed unless a sufficient voltage or sufficient spin current is applied. Accordingly, problems with insufficient recording arise before possible tunnel barrier breaks down.

In the mean time, since the switching current requirements reduce with decreasing MTJ element dimensions, pSTT-MRAM has the potential to scale nicely at the most advanced technology nodes. However, patterning of small MTJ element may lead to increasing variability in MTJ resistance and sustaining relatively high switching current or recording voltage variation in a pSTT-MRAM; accordingly a degradation of MRAM performance would occur. Due to the limitation (such as UV light source and photo-resist thickness) of the current photolithography technology, it is also difficult to form ultra-small photo-resist pillar pattern. Once a cell dimension is getting too small, the photo-resist pillars will not be strong enough to support themselves and bend or tilt; accordingly causing a variation in magnetoresistive element dimensions. More seriously, some photo-resist pillars may collapse before etching; thereby defects are generated.

Thus, it is desirable to form pSTT-MRAM elements with small dimensions by using an ultra small hard mask while employing a mature photolithography process with a good CD uniformity.

### BRIEF SUMMARY OF THE PRESENT INVENTION

The current invention describe a method to make magnetic random access memory with extremely small cell size. Using atomic layer deposition (ALD) technique, a very thin film of hard mask material is uniformly grown on the vertical spatial walls of a pre-form. Stand alone hard mask is formed after removing the pre-form. Array of magnetic memory cells are formed by reactive ion etch (RIE) or ion milling using such small hard mask. This way, the dimension of the hard mask is no longer limited by photolithography tool capability, instead, it is controlled by ALD film thickness which can be made extremely small.

The exemplary embodiment will be described hereinafter with reference to the companying drawings. The drawings are schematic or conceptual, and the relationships between the thickness and width of portions, the proportional coefficients of sizes among portions, etc., are not necessarily the same as the actual values thereof.

### BRIEF DESCRIPTION OF THE DRAWINGS

FIG. 1 Process Flow.

FIG. 2 Substrate with VIAs to be used to connect to the underneath CMOS control circuit (not shown).

FIG. 3 Device film stack including bottom electrode, memory film stack and top hard mask pre-form layer are deposited.

FIG. 4 1^{st} photolithography patterning to create a large pre-form for vertical spatial wall hard mask.

FIG. 5 The exposed portion of the pre-form is etched away.

FIG. 6 Hard mask layer is uniformly deposited on the pre-form wall.

FIG. 7 Hard mask layer is removed from the top and bottom surface by low angle ion mill.

FIG. 8 Pro-form is removed and isolated hard mask array is formed.

FIG. 9A The exposed portion of the memory film stack is etched away.

FIG. 9B The exposed memory layer is partially etched and the etching is stopped on the middle MgO layer.

FIG. 10 2^{nd} photolithography patterning is used to define bottom electrode.

FIG. 11 The exposed area of bottom electrode is removed by etching.

FIG. 12 The etched areas are refilled with dielectric material and CMP is used to flatten the surface.

FIG. 13 Top electrode is made, and isolated magnetic memory cells are formed.

### DETAILED DESCRIPTION OF THE INVENTION

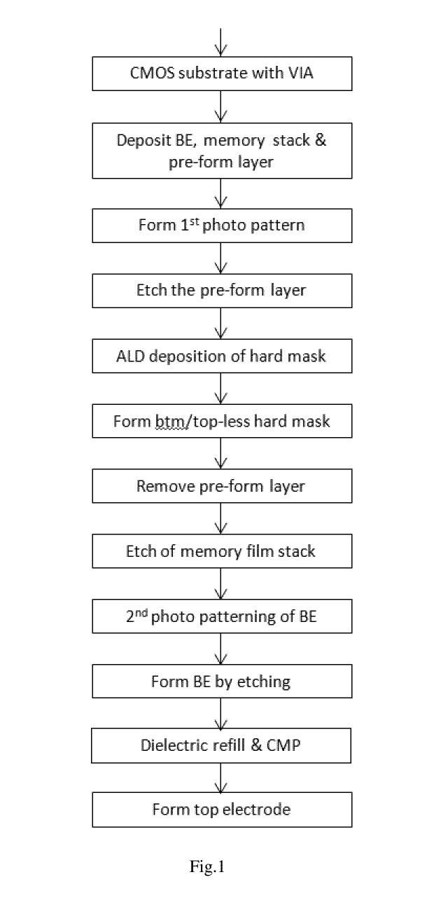

In this invention, we use a so-called spatial wall process to form a hard mask with a very narrow line width. The process flow of the memory fabrication is shown in FIG. 1.

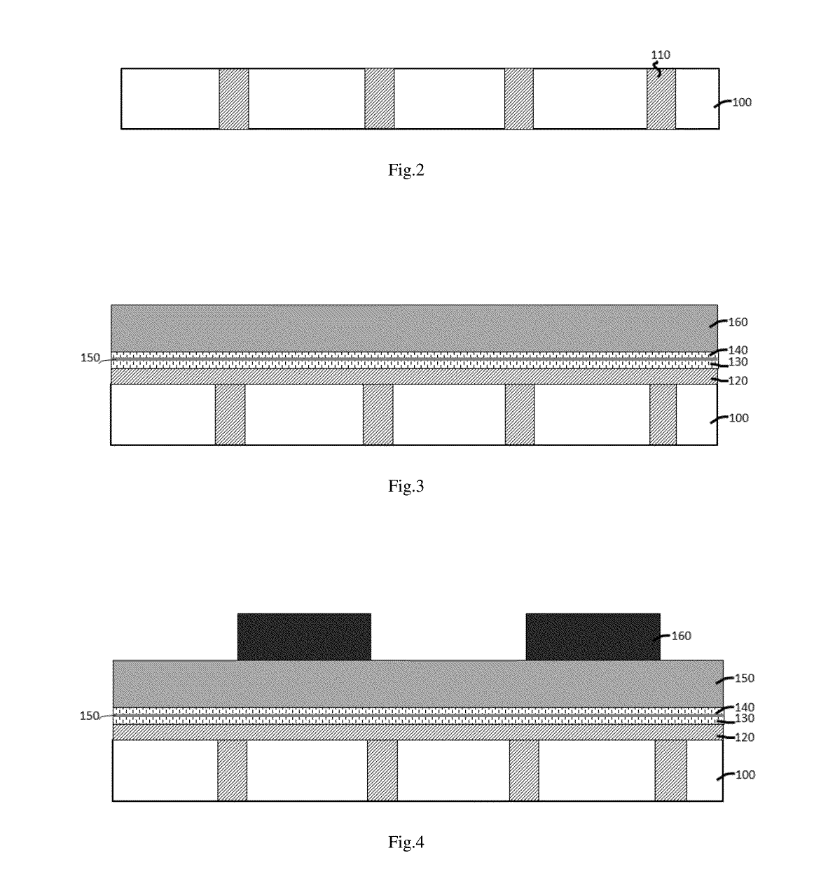

It begins with a pre-fabricated device substrate (100) with built-in VIAs (110) connecting to the underneath CMOS circuit [not shown in FIG. 2]. A full stack of device film is deposited [FIG. 3] starting from bottom electrode (120), magnetic reference layer (130) & memory layer (140), a MgO barrier (150) in between, and top hard mask pre-form layer (160). Typical material for the bottom electrode (120) is an tri-layer of Ta/Ru, Cu or Al & Cu/Ta. For perpendicular p-STT-MRAM, the magnetic reference layer is normally a multilayer of CoPt, CoPd, CoTb, FePt, FePd, FeTb or [Co/Pt]n, [Co/Pd]n, [Co/Ni]n, [Fe/Pt]n, [Fe/Pd]n superlattice, and memory layer is a thin (<30 A) CoFeB or bi-layer of CoFe/CoFeB with a Ru capping layer. The pre-form layer is either amorphous carbon (a-C), SiO2, Al2O3, or other metal oxides.

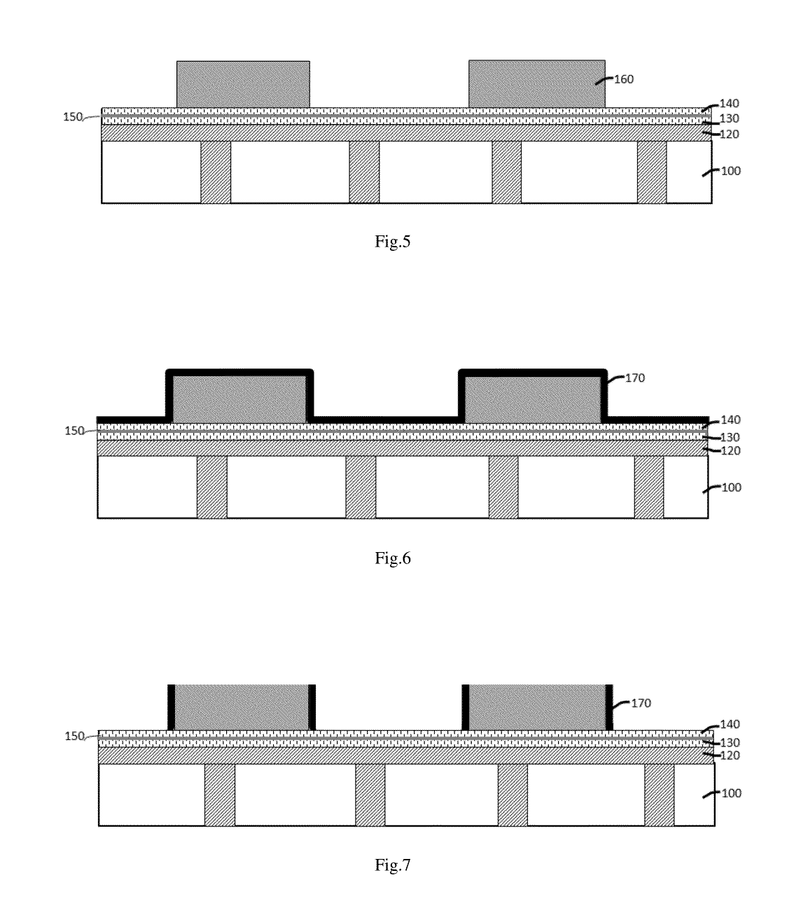

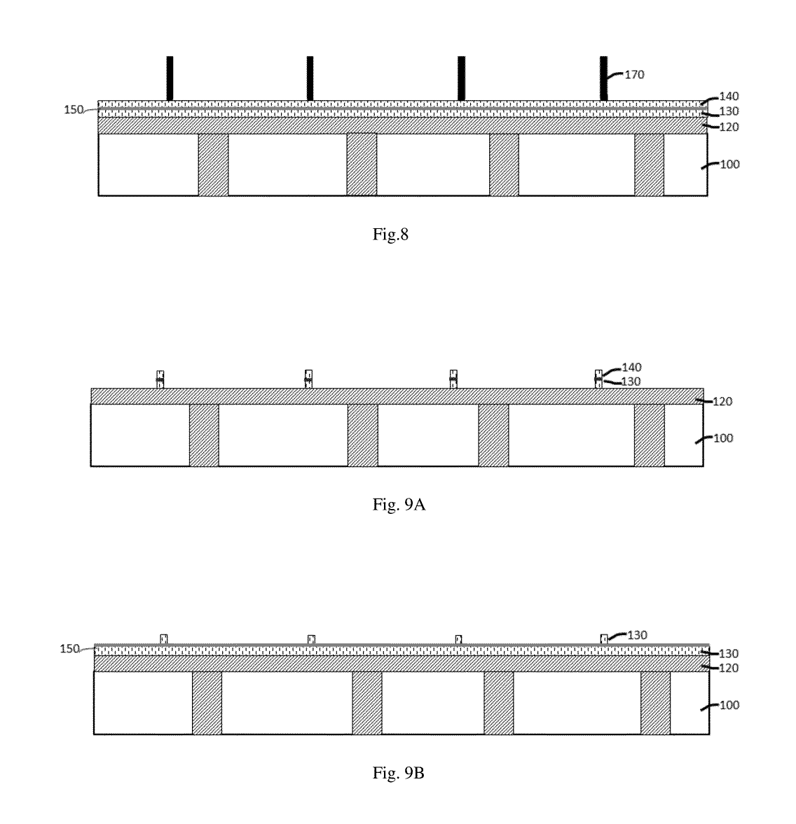

After the film deposition, a photolithography patterning is used to define the pre-form [FIG. 4]. The exposed area of the pre-form material is removed by wet etching if Al2O3, SiO2 or other metal oxide MxOy is used or dry oxygen etch if a-C is used [FIG. 5]. Then, by using a so-called atomic layer deposition (ALD) method, a thin hard mask of Ta or W layer is conformally deposited on all surfaces including the spatial wall of the pre-form [170 in FIG. 6]. Then, the wafer is milled by a perpendicular sputter etch or low angle ion milling to remove the hard mask material from the top and bottom surface (so-called top-less, bottom-less) and leaving vertical spatial wall still covered by the hard mask material [FIG. 7]. Then the wafer is undergone a wet etch process to remove the remaining pre-form Al2O3 in between the hard mask or dry etch if a-C is used, leaving behind array of hard mask (170) vertically sitting on the memory layer [FIG. 8].

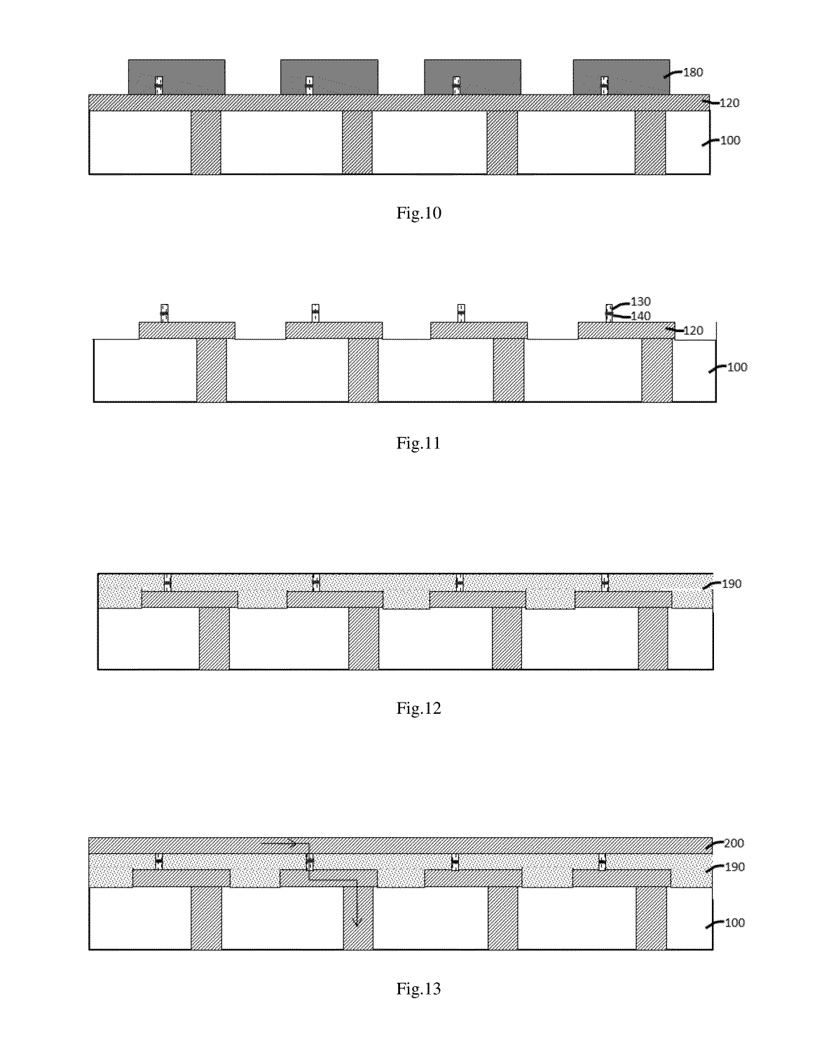

A reactive ion etch (RIE) is used to remove the exposed magnetic layer completely [FIG. 9A] or partially stopped on MgO barrier [FIG. 9B] using a CH3OH or CO/NH3 gas, or ion-milling by Ar ions and post-mill edge oxidation. Then, a second photolithography patterning is used to form bottom electrode [FIG. 10], and the exposed portion of bottom electrode material is etched away [FIG. 11] by RIE or ion milling.

Then, etched area is refilled with a dielectric material (SiO2, SiNx or Al2O3), and the top surface is flattened by chemical mechanical polishing (CMP) [FIG. 12]. And finally, the top electrode is formed by metal (Ta/Ru, Cu or Al & Cu/Ta deposition followed by photolithography patterning and etching, forming array of isolated memory cell with a conducting path shown by the current flow in FIG. 13.

1. A magnetic random access memory (MRAM) with small memory cell size is formed by spatial wall process;

2. The element of claim 1, wherein the MRAM is a spin transfer torque type magnetic random access memory (STT-MRAM), or more specifically a perpendicular spin transfer torque type magnetic random access memory (pSTT-MRAM);

3. The element of claim 1, wherein the MRAM contains a bottom electrode layer, a stack of magnetic device layer, a capping layer, a pre-form layer;

4. The element of claim 3, wherein the bottom electrode is Ta/Ru/Ta tri-layer;

5. The element of claim 3, wherein the magnetic memory device stack contains a magnetic reference layer, magnetic memory layer and a MgO barrier in between and a capping layer on top of the memory layer;

6. The element of claim 3, wherein the magnetic memory device stack contains a reversed film stack: magnetic memory layer, a magnetic reference layer and a MgO barrier in between and a capping layer on top of the reference layer;

7. The element of claim 3, wherein the pre-form layer is SiO2, Al2O3 or amorphous carbon and located on top of magnetic film stack with a thickness between 200 A-500 A;

8. The element of claim 7, wherein the pre-form layer is photolithography patterned;

9. The element of claim 8, wherein the exposed portion of pre-form SiO2 or Al2O3 is wet etched by an acidic solution;

10. The element of claim 8, wherein the exposed portion of pre-form amorphous carbon is dry etched by oxygen;

11. The element of claim 8, wherein a thin layer of hard mask is conformally and uniformally deposited on all surfaces of the etch pre-form including the spatial walls by an atomic layer deposition technique;

12. The element of claim 11, wherein the hard mask material is Ta or W;

13. The element of claim 11, wherein the top and bottom portion of the hard mask is removed by sputtering etch or low angle (perpendicular) ion milling;

14. The element of claim 11, wherein the vertical portion of the hard mask still remains;

15. The element of claim 11, wherein the remaining pre-form material is either wet etched (for SiO2, Al2O3) or dry oxygen etched (for a-C);

16. The element of claim 15, wherein the stand alone array of hard mask is formed;

17. The element of claim 16, wherein the exposed portion of magnetic film stack (outside the hard mask covered area) is etched by reactive ion etch (RIE) or ion milling;

18. The element of claim 17, wherein another photolithography patterning is used to define bottom electrode, and the exposed portion of bottom electrode is removed by RIE or ion milling;

19. The element of claim 18, wherein the etched area is refilled with dielectric material SiO2, or Si3N4, or Al2O3, and the top surface of the dielectric refill is flattened by chemical mechanical polishing (CMP);

20. The element of claim 19, wherein a top electrode is formed on top of the memory layer and dielectric layer by film deposition, photolithography patterning, and RIE or ion milling.
